(19) United States
(12) Patent Application Publication
(10) Pub. No.: US 2011/0280267 A1
(43) Pub. Date: Nov. 17, 2011

(54) SEMICONDUCTOR LASER APPARATUS AND OPTICAL APPARATUS

(75) Inventors: Hideki YOSHIKAWA, Takarazuka-shi (JP); Nobuhiko HAYASHI, Osaka-shi (JP)

(73) Assignee: SANYO ELECTRIC CO., LTD., Moriguchi-shi (JP)

(21) Appl. No.: 13/106,006

(22) Filed: May 12, 2011

(30) Foreign Application Priority Data
May 14, 2010 (JP) 2010-112231
May 31, 2010 (JP) 2010-123965

(51) Int. Cl. H01S 5/02

(52) U.S. Cl. 372/44.01

(57) ABSTRACT

This semiconductor laser apparatus includes a semiconductor laser chip and a package sealing the semiconductor laser chip. The package includes a base body made of resin, a first sealing member mounted on an upper surface of the base body and a translucent second sealing member mounted on a front surface of the base body. The base body has an opening passing through the base body from the upper surface to the front surface, and the side of the opening closer to the upper surface is sealed with the first sealing member, while the side of the opening closer to the front surface is sealed with the second sealing member.

### CROSS-REFERENCE TO RELATED APPLICATION

The priority application numbers JP2010-112231, Semiconductor Laser Apparatus and Optical Apparatus, May 14, 2010, Nobuhiko Hayashi, and JP2010-123965, Semiconductor Laser Apparatus and Optical Apparatus, May 31, 2010, Hideki Yoshikawa et al., upon which this patent application is based are hereby incorporated by reference.

### BACKGROUND OF THE INVENTION

1. Field of the Invention

The present invention relates to a semiconductor laser apparatus and an optical apparatus, and more particularly, it relates to a semiconductor laser apparatus and an optical apparatus each including a package sealing a semiconductor laser chip.

2. Description of the Background Art

A semiconductor laser device has been widely applied as a light source for an optical disc system, an optical communication system or the like in general. For example, an infrared semiconductor laser device emitting a laser beam having a wavelength of about 780 nm has been put into practice as a light source for reading of a CD, and a red semiconductor laser device emitting a laser beam having a wavelength of about 650 nm has been put into practice as a light source for writing/reading of a DVD. A blue-violet semiconductor laser device emitting a laser beam having a wavelength of about 405 nm has been put into practice as a light source for a Blu-ray disc.

In order to attain such a light source apparatus, a semiconductor laser apparatus comprising a package sealing a semiconductor laser chip is known in general, as disclosed in Japanese Patent Laying-Open No. 2009-152330, for example.

Japanese Patent Laying-Open No. 2009-152330 discloses a semiconductor device mounted with a semiconductor laser chip in a metal package having an opening connecting from a front surface to an upper surface and a metal cap formed in a substantially L shape by bending a flat plate for sealing the opening of the package with two surfaces. The package and the cap are bonded to each other by resistance welding.

In the semiconductor device disclosed in Japanese Patent Laying-Open No. 2009-152330, however, the cap is formed by bending the flat plate, and hence a corner portion formed by the bending may be rounded at a prescribed curvature. In this case, a clearance is easily formed between a base portion and the corner portion of the cap, and hence the package cannot be reliably sealed.

### SUMMARY OF THE INVENTION

In order to attain the aforementioned object, a semiconductor laser apparatus according to a first aspect of the present invention includes a semiconductor laser chip and a package sealing the semiconductor laser chip, the package includes a base body made of resin, a first sealing member mounted on an upper surface of the base body and a translucent second sealing member mounted on a front surface of the base body, the base body has an opening passing through the base body from the upper surface to the front surface, and the side of the opening closer to the upper surface is sealed with the first sealing member, while the side of the opening closer to the front surface is sealed with the second sealing member. In the present invention, the term “front surface” denotes a side surface from which the semiconductor laser chip emits a laser beam outward.

In the semiconductor laser apparatus according to the first aspect of the present invention, as hereinabove described, the opening passing through the base body from the upper surface to the front surface is sealed with the first sealing member and the second sealing member, whereby the sides of the opening closer to the upper surface and the front surface respectively can be easily sealed while a clearance is hardly formed on the boundary between the sides of the opening closer to the upper surface and the front surface respectively, dissimilarly to a case where the package is sealed with a sealing member formed by bending. Thus, the package can be so reliably sealed that the semiconductor laser chip in the package can be inhibited from deterioration.

In the aforementioned semiconductor laser apparatus according to the first aspect, the first sealing member and the second sealing member are mounted on the base body through sealants made of resin respectively. According to this structure, the first and second sealing members can be more strongly mounted on the base body through the sealants, with no clearances.

In the aforementioned structure having the first sealing member and the second sealing member mounted on the base body through the sealants, the first sealing member and the second sealing member are preferably bonded to each other through the sealants made of resin, thereby sealing the opening of the base body from the upper surface to the front surface. According to this structure, the first sealing member and the second sealing member can seal a boundary region (boundary portion) where the opening passing through the base body from the upper surface to the front surface changes the direction thereof from the upward direction to the frontward direction with no clearances.

In the aforementioned semiconductor laser apparatus according to the first aspect, the plane area of the first sealing member as viewed from the side of the upper surface is preferably rendered larger than the opening area of the opening on the side closer to the upper surface, and the side of the opening closer to the upper surface is preferably covered with the first sealing member. According to this structure, the first sealing member can reliably seal the side of the opening closer to the upper surface.

In the aforementioned structure having the first sealing member whose plane area is larger than the opening area of the opening on the side closer to the upper surface, the base body is preferably concavely formed with the opening, and the second sealing member is preferably arranged to seal the side of the opening closer to the front surface, surrounded by the inner side surface on the side closer to the front surface of the base body and the lower surface of the first sealing member sealing the side closer to the upper surface of the base body. According to this structure, the second sealing member can reliably seal the side of the opening closer to the upper surface.

In the aforementioned structure having the base body concavely formed with the opening, the second sealing member is preferably fitted into the inner side surface of the opening on the side closer to the front surface. According to this structure, the front surface of the base body and the surface of the second sealing member closer to the front surface can be rendered flush with each other, whereby the second sealing member can be inhibited from protruding frontward from the base body.

In the aforementioned structure having the base body concavely formed with the opening, the semiconductor laser apparatus preferably further includes a metal plate receiving the semiconductor laser chip thereon on the inner bottom surface of the package, and the second sealing member is preferably arranged to seal an opening region in a state coming into contact with a front end surface of the metal plate closer to the front surface. According to this structure, the second sealing member for sealing the opening region can be easily positioned.

In the aforementioned structure having the second sealing member sealing the opening region constituted of the inner side surface on the side closer to the front surface of the base body and the lower surface of the first sealing member, the plane area of the second sealing member as viewed from the side of the front surface is preferably larger than the opening area of the opening on the side closer to the front surface, and the surface on the side closer to the front surface of the base body and the end surface of the first sealing member on the side closer to the front surface are preferably covered with the second sealing member. According to the structure, the second sealing member can reliably seal the side of the opening closer to the front surface.

In the aforementioned semiconductor laser apparatus according to the first aspect, the side of the opening closer to the front surface is preferably notched from a first end portion to a second end portion of the front surface of the base body along a direction orthogonal to a light-emitting direction of the semiconductor laser chip and the thickness direction of the base body, and the second sealing member is preferably fitted into the space between the first end portion and the second end portion of the front surface of the base body. According to this structure, an opening region, into which the second sealing member is fitted, on the side of the opening closer to the front surface can be widely ensured, whereby flexibility for positioning the semiconductor laser chip can be improved. Further, the semiconductor laser apparatus can be formed by easily arranging a plurality of semiconductor laser chips in the package.

In this case, the widths of the opening along the direction orthogonal to the light-emitting direction of the semiconductor laser chip are preferably substantially equal to each other on the side closer to the upper surface and the side closer to the front surface. According to this structure, a sealing space in the package can be formed into a simple shape. Further, the sealing space in the package can be more widely ensured.

In the aforementioned structure having the first sealing member and the second sealing member mounted on the base body through the sealants, outer edge portions of sealed regions of the opening are preferably filled up with the sealants not to generate holes penetrating from an inside of the sealing space to an outside thereof. According to this structure, the sealing space in the package can be reliably isolated from the outer side of the package through the sealants with no holes penetrating from the inside of the sealing space to the outside thereof. Thus, the semiconductor laser chip can be reliably inhibited from deterioration.

In this case, the sealants preferably protrude from the sealed regions of the opening at least into a sealing space of the package. According to this structure, the sealants can be reliably piled up on bonded portions of the base body and the first and second sealing members respectively, at least in the sealing space in the package. Thus, airtightness in the package can be improved.

In the aforementioned semiconductor laser apparatus according to the first aspect, the sealants are preferably made of any of fluororesin, epoxy resin, ethylene-vinyl alcohol resin and a silicone rubber-based tackifier. According to this structure, low molecular siloxane or volatile organic gas present outside the semiconductor laser apparatus (in the atmosphere) can be inhibited from infiltrating into the package through the sealants, whereby formation of adherent substances on a light-emitting facet of the semiconductor laser chip can be suppressed. Consequently, the semiconductor laser chip can be inhibited from deterioration. Particularly in a case where the semiconductor laser apparatus includes a nitride-based semiconductor laser chip, adherent substances are easily formed on the light-emitting facet of the semiconductor laser chip, and hence the aforementioned sealants according to the present invention are effectively employed.

In the aforementioned semiconductor laser apparatus according to the first aspect, the base body preferably has an outer shape tapered toward the front surface as viewed from the side of the upper surface. According to this structure, the semiconductor laser apparatus can be easily built into a housing of an optical pickup or the like through an insertion hole or the like.

In this case, the first sealing member preferably has an outer shape tapered toward the side closer to the front surface as viewed from the side of the upper surface. According to this structure, the outer shape of the first sealing member can be conformed to the outer shape of the base body tapered toward the front surface, whereby the semiconductor laser apparatus can be easily built into a housing of an optical pickup or the like through an insertion hole or the like.

In the aforementioned structure having the first sealing member and the second sealing member mounted on the base body through the sealants, the sealants are preferably provided to extend onto a surface of the first sealing member other than a bonded region bonded to the base body. According to this structure, the strength (rigidity) of the first sealing member can be improved also when the first sealing member has a small thickness. Further, the rigidity is so improved that the first sealing member can be prevented from unnecessary deformation and is easily handled in manufacturing steps.

The aforementioned semiconductor laser apparatus according to the first aspect preferably further includes a metal plate receiving the semiconductor laser chip thereon on the inner bottom surface of the package, and the metal plate preferably includes a heat radiation portion extending outward from the base body. According to this structure, heat generated by the semiconductor laser chip can be easily radiated outward from the package through the heat radiation portion of the metal plate. Further, the semiconductor laser apparatus can be mounted on and fixed to a housing of an optical pickup or the like, for example, through the heat radiation portion extending outward from the base portion. Thus, the heat generated by the semiconductor laser chip can be easily radiated to the housing.

In the aforementioned structure further including the metal plate, the base body preferably has an outer shape tapered toward the front surface as viewed from the side of the upper surface, and the heat radiation portion preferably extends outward from an outer side surface other than a region tapered toward the front surface of the base body. According to this structure, the semiconductor laser apparatus can be more easily built into a housing of an optical pickup or the like through an insertion hole or the like.

In the aforementioned semiconductor laser apparatus according to the first aspect, the semiconductor laser chip is preferably a nitride-based semiconductor laser chip. In the nitride-based semiconductor laser chip having a short lasing wavelength and requiring a higher output, adherent substances are easily formed on a light-emitting facet thereof. Therefore, it is extremely effective to reliably seal the opening with the aforementioned “first sealing member” and “second sealing member” according to the present invention, in order to inhibit the nitride-based semiconductor laser chip from deterioration.

An optical apparatus according to a second aspect of the present invention includes a semiconductor laser apparatus including a semiconductor laser chip and a package sealing the semiconductor laser chip and an optical system controlling a beam emitted from the semiconductor laser apparatus, the package includes a base body made of resin, a first sealing member mounted on an upper surface of the base body and a translucent second sealing member mounted on a front surface of the base body, the base body has an opening passing through the base body from the upper surface to the front surface, and the side of the opening closer to the upper surface is sealed with the first sealing member, while the side of the opening closer to the front surface is sealed with the second sealing member.

In the optical apparatus according to the second aspect of the present invention, as hereinabove described, the opening passing through the base body from the upper surface to the front surface is sealed with the first sealing member and the second sealing member, whereby the sides of the opening closer to the upper surface and the front surface respectively can be easily sealed while a clearance is hardly formed on the boundary between the sides of the opening closer to the upper surface and the front surface respectively, dissimilarly to a case where the package is sealed with a sealing member formed by bending. Thus, the package can be so reliably sealed that the semiconductor laser chip in the package can be inhibited from deterioration. Consequently, an optical apparatus, having a hardly deteriorated semiconductor laser chip, highly reliable and capable of withstanding long-term use can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view showing a semiconductor laser apparatus according to a first embodiment of the present invention in a state where a base portion and sealing members are separated from each other;

FIG. 2 is a perspective view showing the semiconductor laser apparatus according to the first embodiment of the present invention in a state where the sealing members are mounted on the base portion;

FIG. 3 is a top plan view showing the semiconductor laser apparatus according to the first embodiment of the present invention in a state where a first sealing member is removed;

FIG. 4 is a longitudinal sectional view of the semiconductor laser apparatus according to the first embodiment of the present invention taken along a centerline in the width direction;

FIG. 5 is a front elevational view of the semiconductor laser apparatus according to the first embodiment of the present invention, as viewed from a light-emitting direction;

FIGS. 6 to 9 are top plan views for illustrating a manufacturing process for the semiconductor laser apparatus according to the first embodiment of the present invention;

FIG. 10 is a longitudinal sectional view of a semiconductor laser apparatus according to a first modification of the first embodiment of the present invention taken along a centerline in the width direction;

FIG. 11 is a longitudinal sectional view of a semiconductor laser apparatus according to a second modification of the first embodiment of the present invention taken along a centerline in the width direction;

FIG. 12 is a longitudinal sectional view of a semiconductor laser apparatus according to a third modification of the first embodiment of the present invention taken along a centerline in the width direction;

FIG. 13 is a perspective view showing a semiconductor laser apparatus according to a second embodiment of the present invention in a state where sealing members are mounted on a base portion;

FIG. 14 is a perspective view showing a semiconductor laser apparatus according to a third embodiment of the present invention in a state where sealing members are mounted on a base portion;

FIG. 15 is a top plan view showing a semiconductor laser apparatus according to a fourth embodiment of the present invention in a state where a first sealing member is removed;

FIG. 16 is a front elevational view of the semiconductor laser apparatus according to the fourth embodiment of the present invention, as viewed from a light-emitting direction;

FIG. 17 is a schematic diagram showing the structure of an optical pickup according to a fifth embodiment of the present invention;

FIG. 18 is a block diagram of an optical disc apparatus including an optical pickup according to a sixth embodiment of the present invention;

FIG. 19 is a front elevational view of an RGB three-wavelength semiconductor laser apparatus according to a seventh embodiment of the present invention, as viewed from a light-emitting direction;

FIG. 20 is a block diagram of a projector including the RGB three-wavelength semiconductor laser apparatus according to the seventh embodiment of the present invention;

FIG. 21 is a block diagram of a projector according to an eighth embodiment of the present invention; and

FIG. 22 is a timing chart showing a state where a control portion transmits signals in a time-series manner in the projector according to the eighth embodiment of the present invention.

### DESCRIPTION OF THE PREFERRED EMBODIMENTS

Embodiments of the present invention are now described with reference to the drawings.

### First Embodiment

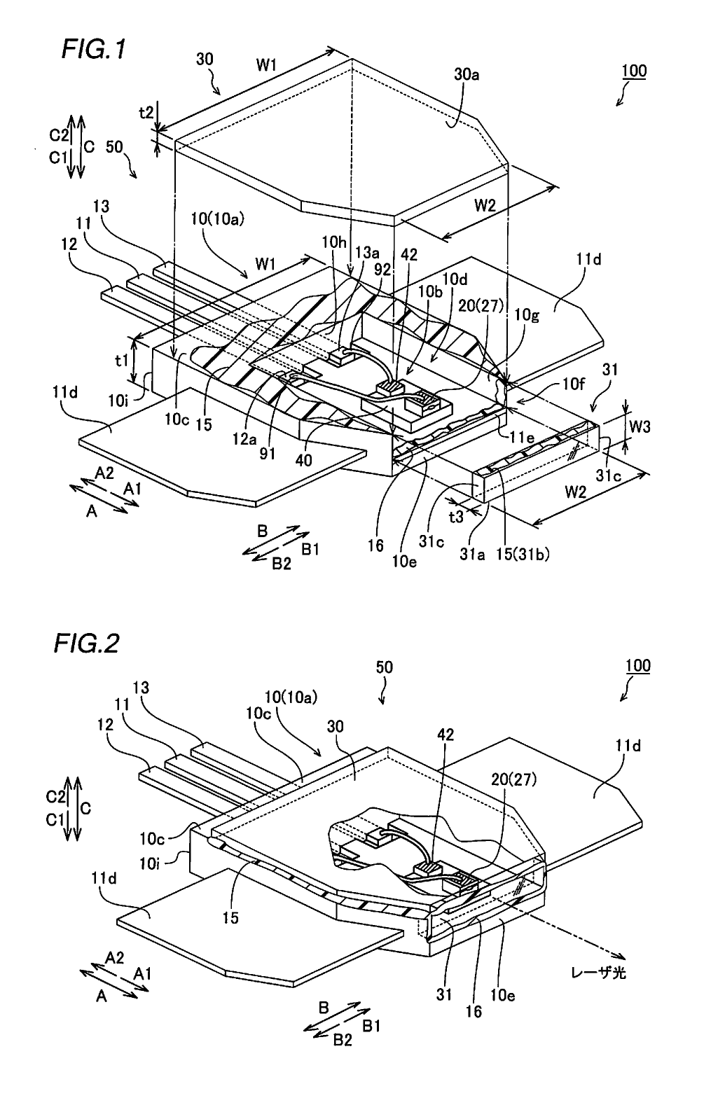

First, the structure of a semiconductor laser apparatus 100 according to a first embodiment of the present invention is described with reference to FIGS. 1 to 5. FIG. 2 omits partial reference numerals, in order to show states of a semiconductor laser chip sealed in a package and the periphery thereof.

The semiconductor laser apparatus 100 according to the first embodiment of the present invention is constituted of a blue-violet semiconductor laser chip 20 having a lasing wavelength of about 405 nm and a package 50 sealing the blue-violet semiconductor laser chip 20. The package 50 has a base portion 10 mounted with the blue-violet semiconductor laser chip 20 and sealing members 30 and 31 mounted on the base portion 10 for covering the blue-violet semiconductor laser chip 20 from above (from the side along arrow C2) and from the front side (from the side along arrow A1) respectively. The blue-violet semiconductor laser chip 20 is an example of the “semiconductor laser chip” in the present invention. The sealing members 30 and 31 are examples of the “first sealing member” and the “second sealing member” in the present invention respectively.

The base portion 10 has a flat base body 10a, made of polyamide resin, having a thickness t1 (in a direction C) and a width W1 (in a direction B). A recess portion 10b having a depth of about half the thickness t1 is formed in a prescribed region of an upper surface 10c (surface along arrow C2) of the flat base body 10a closer to a front surface 10e (surface along arrow A1). The recess portion 10b has an opening 10d on the side of the upper surface 10c and another opening 10f on the side of the front surface 10e. The openings 10d and 10f communicate with each other from the upper surface 10c toward the front surface 10e, and have a width W2 (in the direction B, W2<W1) in common with each other. The opening 10f is formed by notching the front surface 10e from an end portion along arrow B1 up to another end portion along arrow B2. The recess portion 10b is constituted of a pair of side wall portions 10g substantially parallelly extending rearward (along arrow A2) from both end portions (in the direction B) of the opening 10f, an inner wall portion 10h connecting rear end portions (along arrow A2) of the side wall portions 10g with each other and a bottom surface 10j connected with the side wall portions 10g and the inner wall portion 10h on lower portions (along arrow C1). The bottom surface 10j is an example of the “inner bottom surface” in the present invention. The end portions of the front surface 10e along arrows B1 and B2 are examples of the “first end portion” and the “second end portion” in the present invention respectively.

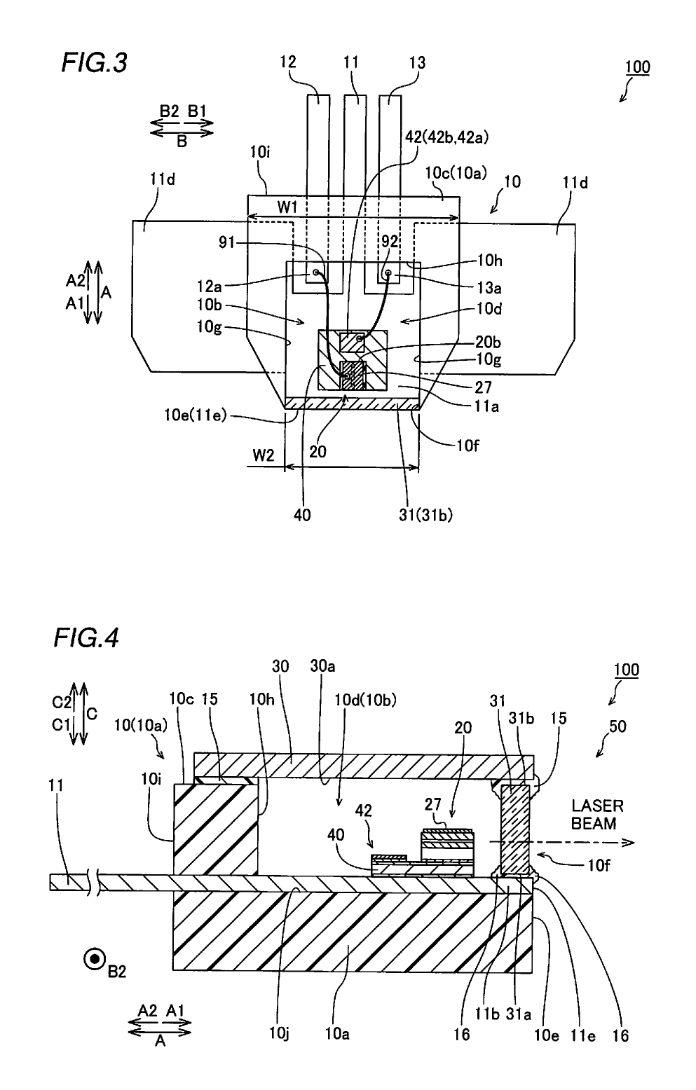

As shown in FIG. 3, the base body 10a has an outer shape so tapered that the width (in the direction B) thereof is reduced from the rear side (along arrow A2) toward the front surface 10e.

The base portion 10 is provided with lead frames 11, 12 and 13 made of metal. The lead frames 11 to 13 are arranged to pass through the base body 10 from the front side (along arrow A1) toward the rear side (along arrow A2) in a state insulated from each other. The lead frame 11 passes through a substantially central portion of the base body 10a in the width direction (direction B), as viewed from the side of the upper surface 10c. The lead frames 12 and 13 are arranged on the outer sides (along arrows B2 and B1) of the lead frame 11 in the direction B respectively.

Rear end regions of the lead frames 11 to 13 extending rearward (along arrow A2) are exposed from a rear surface 10i (along arrow A2: see FIG. 3) of the base body 10a respectively. Front end regions 11a, 12a and 13a of the lead frames 11, 12 and 13 extending frontward (along arrow A1) are exposed from the inner wall portion 10h respectively, and arranged on the bottom surface 10j of the recess portion 10b together. The front end region 11a extends up to the front surface 10e frontward beyond the front end regions 12a and 13a, and spreads in the direction B on the bottom surface 10j of the recess portion 10b. The lead frame 11 is an example of the “metal plate” in the present invention.

The lead frame 11 is integrally provided with a pair of heat radiation portions 11d connected to the front end region 11a. The pair of heat radiation portions 11d are substantially symmetrically arranged on both sides of the lead frame 11 in the direction B. The heat radiation portions 11a extend from the front end region 11a and further extend outward from the base portion 10 from both outer side surfaces of the base body 10a while passing through the base body 10a along arrows B1 and B2, to be exposed. The heat radiating portions 11d, extending outward from side surfaces of the base body 10a other than side surfaces of the tapered portion thereof, may also extend outward from the side surfaces of the tapered portion of the base body 10a.

The sealing member 30 is formed by a flat aluminum plate having a thickness t2 (in the direction C) of about 50 μm. The sealing member 30 is substantially identical in plane shape to the base body 10a, and has a rear width W1 (along arrow A2) and a front width W2 (along arrow A1). The sealing member 30 is mounted on the base portion 10 from above the opening 10d. On the other hand, the sealing member 31 is formed by a translucent flat plate made of silicon resin. The sealing member 31 has a thickness t3 (in a direction A) of about 50 μm, a width W2 (in the direction B) and a height W3 (in the direction C) substantially equal to the depth of the recess portion 10b, and is mounted in the opening 10f.

A sealant 16 continuously covering the inner side surfaces (the upper surface of the front end region 11a of the lead frame 11 in the opening 10f and the inner side surfaces of the pair of side wall portions 10g) of the opening 10f is applied between the sealing member 31 and the base body 10a with a prescribed thickness. The sealing member 31 is mounted in a state bringing a lower surface 31a and both side surfaces 31c thereof into close contact with the sealant 16. Another sealant 15 continuously covering the upper surface 10c (a region close to the inner wall portion 10h and the upper surfaces of the pair of side wall portions 10g) of the base body 10a and the upper surface 31b of the sealing member 31 is applied between the sealing member 30 and the base body 10a and the sealing member 31 with a prescribed thickness, to surround the opening 10d. A rear surface (lower surface) 30a of the sealing member 30 around an outer edge portion is mounted on the upper surface 10c of the base body 10a and the upper surface 31b of the sealing member 31 through the sealant 15. The sealants 15 and 16 are solidified in a state protruding from regions, to which the sealing member 31 is bonded, of the inner side surfaces of the opening 10f into a sealing space of the package 50 and to the outer sides thereof. The sealants 15 and 16 are made of epoxy resin containing bisphenol A and bisphenol F without containing halogen.

The blue-violet semiconductor laser chip 20 formed by a nitride-based semiconductor laser chip is mounted on a substantially central portion of the upper surface of the front end region 11a of the lead frame 11 through a conductive submount 40.

The blue-violet semiconductor laser chip 20 is mounted in a junction-up system while directing a light-emitting surface toward the side of the sealing member 31 (along arrow A1). In a pair of cavity facets formed on the blue-violet semiconductor laser chip 20, that emitting a laser beam having relatively large light intensity serves as the light-emitting surface and that having relatively small light intensity serves as a light-reflecting surface. The blue-violet semiconductor laser chip 20 emits the laser beam along arrow A1. An end of a metal wire 91 made of Au or the like is wire-boned to a p-side electrode 27 formed on the upper surface of the blue-violet semiconductor laser chip 20, while another end of the metal wire 91 is connected to the front end region 12a of the lead frame 12. An n-side electrode (not shown) formed on the lower surface of the blue-violet semiconductor laser chip 20 is electrically connected to the front end region 11a of the lead frame 11 through the submount 40.

A PD (photodiode) 42 employed for monitoring the light intensity of the laser beam is arranged on a rear portion (along arrow A2) of the submount 40 closer to the light-reflecting surface of the blue-violet semiconductor laser chip 20 while directing a photoreceiving surface thereof upward (along arrow C2). The lower surface of the PD 42 is electrically connected to the submount 40. An end of a metal wire 92 made of Au or the like is bonded to the upper surface of the PD 42, while another end of the metal wire 92 is connected to the front end region 13a of the lead frame 13. The semiconductor laser apparatus 100 according to the first embodiment is formed in the aforementioned manner.

A manufacturing process for the semiconductor laser apparatus 100 according to the first embodiment is now described with reference to FIGS. 1 and 6 to 9.

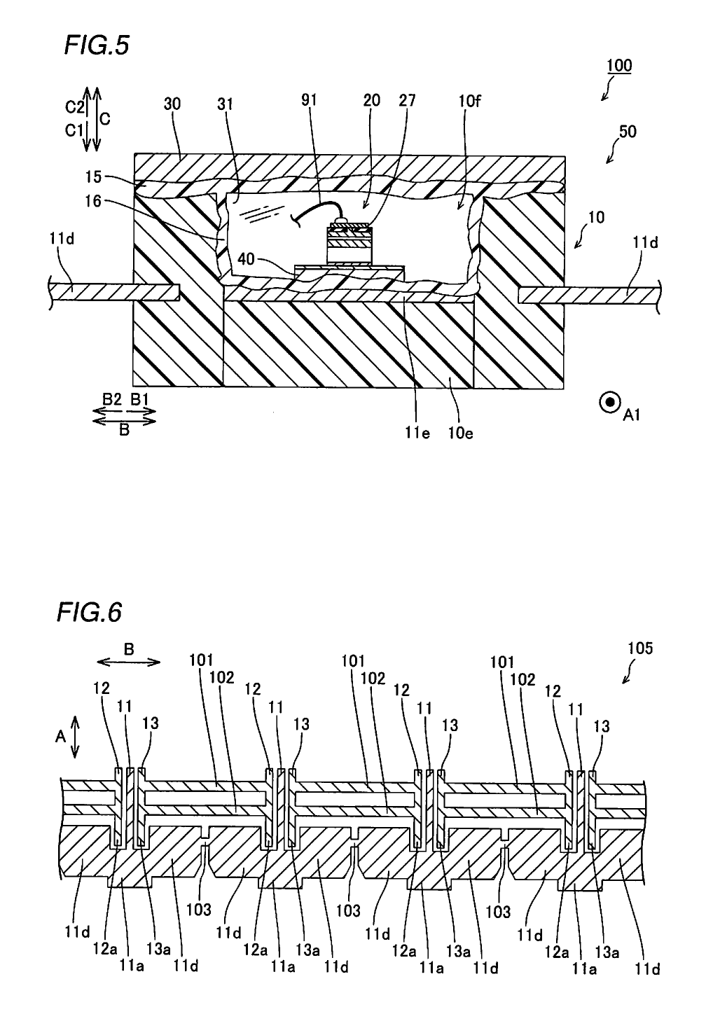

First, a metal plate consisting of a strip-shaped thin plate of iron or copper is so etched as to form a lead frame 105 on which lead frames 11 having heat radiation portions 11d integrally formed along with front end regions 11a and lead frames 12 and 13 arranged on both sides of the lead frames 11 are repeatedly patterned in the transverse direction (direction B), as shown in FIG. 6. At this time, the lead frames 12 and 13 are patterned in a state coupled with each other by coupling portions 101 and 102 extending in the transverse direction (direction B). The heat radiation portions 11d are patterned in a state coupled with each other by coupling portions 103 extending in the transverse direction.

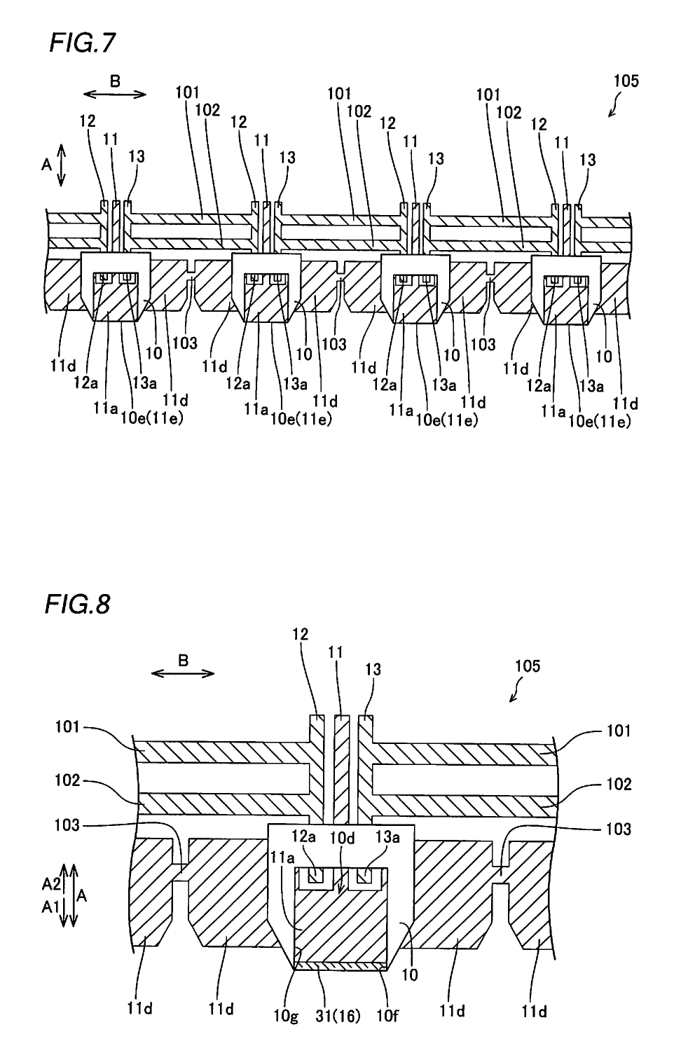

Thereafter base bodies 10a having recess portions 10b are so molded with a resin molding apparatus that sets of the lead frames 11 to 13 pass through the same and front end regions 11a to 13a thereof are exposed on bottom surfaces 10j, as shown in FIG. 7. The base bodies 10a are so molded that front surfaces 10e thereof are flush with front end surfaces 11e of the front end regions 11a of the lead frames 11.

Thereafter the sealant 16 (see FIG. 1) is applied to the inner side surfaces (the upper surface of the front end region 11a in each opening 10f and the inner side surfaces of each pair of side wall portions 10g) of the opening 10f, as shown in FIG. 8. Then, the sealing member 31 is mounted, to be fitted into the opening 10f. At this time, the sealant 16 is cured by heating the same under a temperature condition of at least about 80° C. and not more than about 200° C. for a prescribed time (about 30 minutes). Thus, the sealing member 31 is mounted on the base body 10a in a state bringing the lower surface 31a and both side surfaces 31c thereof into close contact with the upper surface of the front end region 11a and the inner side surfaces of the side wall portions 10g through the sealant 16.

Thereafter each base portion 10 is subjected to UV cleaning treatment or heating treatment at about 200° C. in vacuum. Thus, contaminations adhering to the recess portion 10b in the manufacturing process and fluid, a solvent etc. contained in polyamide resin are evaporated and removed.

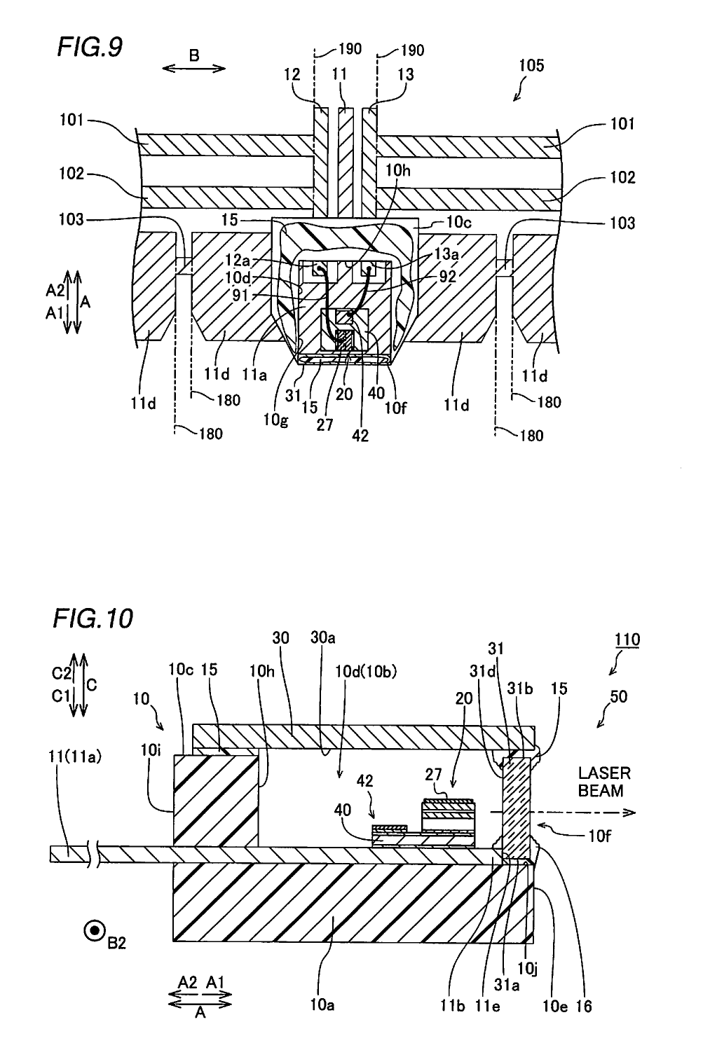

Then, each submount 40 provided with the blue-violet semiconductor laser chip 20 and the PD 42 is bonded to a substantially central portion (in the transverse direction) of the upper surface of the corresponding front end region 11a through a conductive adhesive layer (not shown), as shown in FIG. 9. At this time, the light-emitting surface of the blue-violet semiconductor laser chip 20 is directed toward the sealing member 31, while the light-reflecting surface of the blue-violet semiconductor laser chip 20 and the PD 42 are directed toward the inner wall portion 10h.

Thereafter the p-side electrode 27 of the blue-violet semiconductor laser chip 20 and the front end region 12a of the lead frame 12 are connected with each other through the metal wire 91. Further, the upper surface of the PD 42 and the front end region 13a of the lead frame 13 are connected with each other through the metal wire 92.

Thereafter the sealant 15 is applied to continuously cover the upper surface 10c (the region close to the inner wall portion 10h and the upper surfaces of the pair of side wall portions 10g) of the base body 10a and the upper surface 31b of the sealing member 31 and to surround the opening 10d, as shown in FIG. 9. In this state, the sealing member 30 substantially identical in plane shape (see FIG. 1) to the base body 10a is press-bonded to the upper surface 10c of the base body 10a and the upper surface 31b of the sealing member 31, to cover the opening 10d. At this time, the sealant 15 is cured by heating the same under a temperature condition of at least about 80° C. and not more than about 200° C. for a prescribed time (about 30 minutes). Thus, the sealing member 30 is mounted on the base body 10a in a state bringing the rear surface 30a thereof into close contact with the upper surface 10c of the base body 10a and the upper surface 31b of the sealing member 31 through the sealant 15.

Thereafter the coupling portions 101, 102 and 103 are cut and removed along separation lines 180 and 190, as shown in FIG. 9. Thus, the semiconductor laser apparatus 100 according to the first embodiment is manufactured.

According to the first embodiment, as hereinabove described, the openings 10d and 10f passing through the base body 10a from the upper surface 10c to the front surface 10e are sealed with the sealing members 30 and 31 respectively, whereby the sides of the openings 10d and 10f closer to the upper surface 10c and the front surface 10e respectively can be easily sealed while a clearance is hardly formed on the boundary between the sides of the openings 10d and 10f closer to the upper surface 10c and the front surface 10e respectively, dissimilarly to a case where the package 50 is sealed with a sealing member formed by bending. Thus, the package 50 can be reliably sealed, whereby the blue-violet semiconductor laser chip 20 in the package 50 can be inhibited from deterioration.

The sealing members 30 and 31 are mounted on the base body 10a through the sealants 15 and 16 made of resin respectively. Thus, the sealing members 30 and 31 can be more strongly mounted on the base body 10a through the sealants 15 and 16, with no clearances. Further, the sealing members 30 and 31 are so mounted on the base body 10a through the sealants 15 and 16 that the semiconductor laser apparatus 100 can be easily manufactured through an existing manufacturing apparatus without increasing the manufacturing cost.

The sealing members 30 and 31 are bonded to each other through the sealant 15 made of resin, thereby sealing the recess portion 10b of the base body 10a from the opening 10d in the upper surface 10c to the opening 10f in the front surface 10e. Thus, the sealing members 30 and 31 can seal a boundary region (boundary portion) where the openings 10d and 10f in the upper surface 10c and the front surface 10e change the direction thereof from the upward direction (along arrow C2) to the frontward direction (along arrow A1) with no clearances.

The plane area of the sealing member 30 is rendered larger than the opening area (on the side closer to the upper surface 10c) of the opening 10d, which is covered with the sealing member 30. Thus, the sealing member 30 can reliably seal the opening 10d.

The sealing member 31 is arranged to seal an opening region (opening 10f) surrounded by the inner side surfaces (the side wall portions 10g around the opening 10f and the bottom surface 10j) of the recess portion 10b of the base body 10a and the rear surface 30a of the sealing member 30. Thus, the sealing member 31 can reliably seal the opening 10f. Further, the sealing member 31 is fitted into the opening 10f. Thus, the front surface 10e of the base body 10a and the surface of the sealing member 31 closer to the front surface 10e can be rendered flush with each other, whereby the sealing member 31 can be inhibited from protruding frontward (along arrow A1) from the base body 10a.

The opening 10f is formed by notching the front surface 10e from the end portion along arrow B1 to the end portion along arrow B2 along the direction B orthogonal to the light-emitting direction (direction A) of the blue-violet semiconductor laser chip 20 and the thickness direction (direction C) of the base body 10a, and the sealing member 31 is fitted into the space between the end portions of the front surface 10e along arrows B1 and B2. Thus, the opening region (in the direction B) of the opening 10f having the sealing member 31 fitted thereinto can be widely ensured, whereby flexibility for positioning the blue-violet semiconductor laser chip 20 can be improved.

The opening 10d has the same width W2 along the direction B orthogonal to the light-emitting direction of the blue-violet semiconductor laser chip 20 and the thickness direction of the base body 10a on the sides closer to the upper surface 10c and the front surface 10e respectively. Thus, the sealing space in the package 50 can be formed into a simple shape. Further, the sealing space in the package 50 can be more widely ensured.

Outer edge portions of sealed regions (regions close to the inner wall portion 10h, the upper surfaces of the side wall portions 10g, the upper surface of the front end region 11a of the lead frame 11 in the opening 10f and the inner side surfaces of the side wall portions 10g) of the openings 10d an 10f are filled up with the sealants 15 and 16 not to generate holes penetrating from the inside of the sealing space to the outside thereof. Thus, the sealing space of the package 50 can be reliably isolated from the outer side of the package 50 through the sealants 15 and 16 with no holes penetrating from the inside of the sealing space to the outside thereof. Therefore, the blue-violet semiconductor laser chip 20 can be reliably inhibited from deterioration.

The sealants 15 and 16 are solidified in the state protruding from the sealed region of the opening 10d into the sealing space of the package 50 and to the outer side thereof. Thus, the sealants 15 and 16 can be reliably piled up on the bonded portions of the base body 10a and the sealing members 30 and 31 respectively. Therefore, airtightness in the package 50 can be improved.

The sealants 15 and 16 are made of the epoxy resin having gas barrier properties blocking the open air in addition to properties hardly generating volatile components. Therefore, low molecular siloxane or volatile organic gas present outside the semiconductor laser apparatus 100 (in the atmosphere) can be inhibited from infiltrating into the package 50 through the sealants 15 and 16, whereby formation of adherent substances on the light-emitting facet can be suppressed. Consequently, the blue-violet semiconductor laser chip 20 can be inhibited from deterioration.

The base body 10a has the outer shape tapered toward the front surface 10e as viewed from the side of the upper surface 10c. Thus, the semiconductor laser apparatus 100 can be easily built into a housing of an optical pickup or the like through an insertion hole or the like.

The sealing member 30 has the outer shape tapered toward the front surface 10e as viewed from the side of the upper surface 10c. Thus, the outer shape of the sealing member 30 can be conformed to the outer shape of the base body 10a tapered toward the front surface 10e, whereby the semiconductor laser apparatus 100 can be more easily built into a housing of an optical pickup or the like through an insertion hole or the like.

The lead frame 11 includes the heat radiation portions 11d extending outward from the base body 10a. Thus, heat generated by the blue-violet semiconductor laser chip 20 can be easily radiated outward from the package 50 through the heat radiation portions 11d connected to the lead frame 11 (front end region 11a). Further, the semiconductor laser apparatus 100 can be mounted on and fixed to a housing of an optical pickup or the like through the heat radiation portions 11d extending outward from the base portion 10. Thus, the heat generated by the blue-violet semiconductor laser chip 20 can be easily radiated to the housing.

The blue-violet semiconductor laser chip 20 is placed in the package 50. In the nitride-based semiconductor laser chip having a short lasing wavelength and requiring a higher output, adherent substances are easily formed on the light-emitting facet thereof. Therefore, it is extremely effective to reliably seal the openings 10d and 10f with the sealing members 30 and 31, in order to inhibit the blue-violet semiconductor laser chip 20 from deterioration.

### First Modification of First Embodiment

A first modification of the first embodiment is now described. In a semiconductor laser apparatus 110 according to the first modification of the first embodiment, a sealing member 31 is bonded onto a bottom surface 10j of a recess portion 10b exposed in an opening 10f through a sealant 16, as shown in FIG. 10. An inner side surface 31d (along arrow A2) of the sealing member 31 is in contact with a front end surface 11e of a lead frame 11. The remaining structure of the semiconductor laser apparatus 110 according to the first modification of the first embodiment is similar to that of the semiconductor laser apparatus 100 according to the first embodiment, and portions identical to those of the first embodiment are shown by the same reference numerals in FIG. 10.

In a manufacturing process for the semiconductor laser apparatus 110, a base body 10a is so molded that the bottom surface 10j of the recess portion 10b is exposed frontward (along arrow A1) beyond a front end region 11a of the lead frame 11 in FIG. 7. The sealing member 31 is bonded onto the bottom surface 10j exposed in the opening 10f through the sealant 16, thereby sealing the opening 10f. The remaining steps of the manufacturing process are similar to those of the manufacturing process for the semiconductor laser apparatus 100 according to the first embodiment.

In the first modification of the first embodiment, as hereinabove described, the sealing member 31 is mounted on the bottom surface 10j of the recess portion 10b exposed in the opening 10f, and bonded to the base body 10a in the state bringing the inner side surface 31d (along arrow A2) thereof into contact with the front end surface 11e of the lead frame 11. Thus, the sealing member 31 can be easily positioned in the anteroposterior direction (direction A). The remaining effects of the first modification are similar to those of the first embodiment.

### Second Modification of First Embodiment

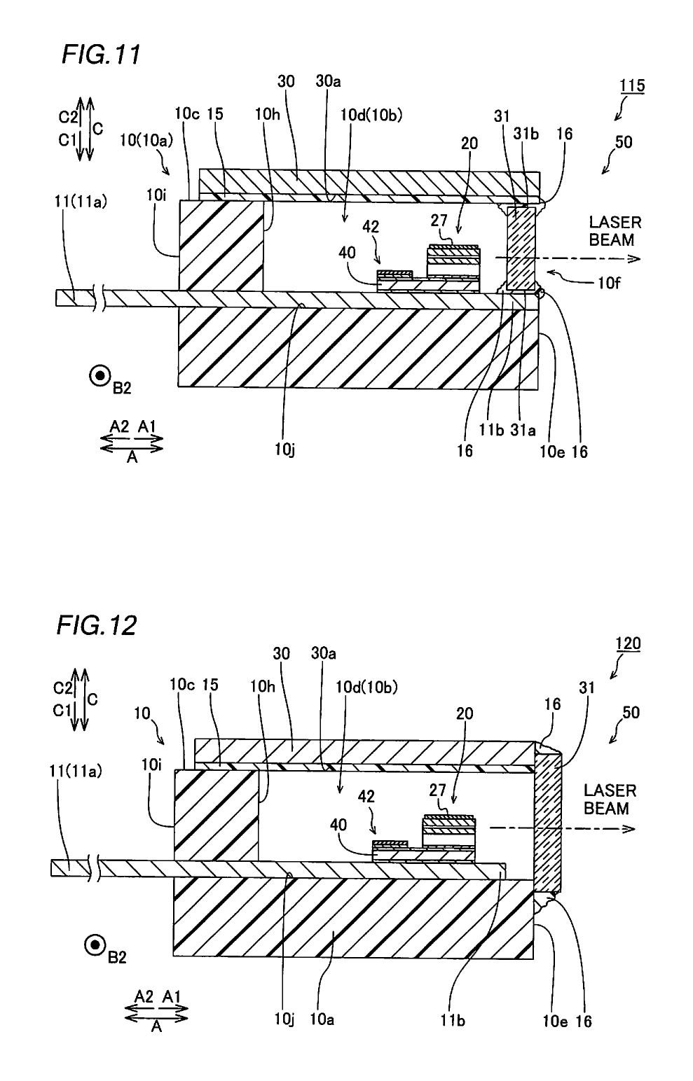

A second modification of the first embodiment is now described. In a semiconductor laser apparatus 115 according to the second modification of the first embodiment, a sealing member 30 is formed by an aluminum plate having a thickness (t2) of about 50 μm, and a sealant 15 is formed substantially on the overall rear surface 30a of the sealing member 30 with a thickness of about 0.2 mm. In the second modification of the first embodiment, the sealant 15 is prepared from Eval (registered trademark), which is resin (EVOH resin) consisting of an ethylene-polyvinyl alcohol copolymer. The remaining structure of the semiconductor laser apparatus 115 according to the second modification of the first embodiment is substantially similar to that of the semiconductor laser apparatus 100 according to the first embodiment, and portions identical to those of the first embodiment are shown by the same reference numerals in FIG. 11.

In a manufacturing process for the semiconductor laser apparatus 115, the sealing member 30 is formed by applying the sealant 15 (EVOH resin), heated to about 220° C., to the overall rear surface 30a with the thickness of about 0.2 mm and cutting the aluminum plate into a prescribed shape after the sealant 15 is cooled. The remaining steps of the manufacturing process are similar to those of the manufacturing process for the semiconductor laser apparatus 100 according to the first embodiment.

In the second modification of the first embodiment, as hereinabove described, the sealant 15 is prepared from the EVOH resin. The EVOH resin has excellent gas barrier properties, and is mainly applied to a food wrapper or the like as a multilayer film. Therefore, low molecular siloxane or volatile organic gas present outside the semiconductor laser apparatus 115 (in the atmosphere) can be inhibited from infiltrating into a package 50 through the sealant 15 and another sealant 16, whereby formation of adherent substances on a light-emitting facet can be suppressed. Consequently, a blue-violet semiconductor laser chip 20 can be inhibited from deterioration. Particularly in the semiconductor laser apparatus 115 including the blue-violet semiconductor laser chip 20, adherent substances are easily formed on the light-emitting facet of the laser chip 20, and hence it is effective to employ the sealant 15 made of the EVOH resin.

The sealant 15 made of the EVOH resin is formed on the overall rear surface 30a of the sealing member 30, whereby physical strength (rigidity) can be increased also when the thickness of the aluminum plate is small. Thus, the material cost can be reduced. Further, the rigidity is so increased that the sealing member 30 can be prevented from unnecessary deformation and easily handled in manufacturing steps. The remaining effects of the second modification are similar to those of the first embodiment.

### Third Modification of First Embodiment

A third modification of the first embodiment is now described. In a semiconductor laser apparatus 120 according to the third modification of the first embodiment, a sealing member 31 having a larger plane area than an opening 10f is mounted on a base body 10a and a sealing member 30 from the front side (along arrow A1), as shown in FIG. 12. FIG. 12 shows portions similar to those of the first modification of the first embodiment with the same reference numerals.

In a manufacturing process for the semiconductor laser apparatus 120, a blue-violet semiconductor laser chip 20 and a PD 42 are bonded onto a front end region 11a and metal wires 91 and 92 are bonded thereto before the sealing member 31 is bonded.

Thereafter the sealing member 30 is mounted on the base body 10a, similarly to the second modification of the first embodiment. Thereafter the sealing member 31 is brought into contact with a front surface 10e of the base body 10a and the front surface of the sealing member 30, to cover the opening 10f. Further, a sealant 16 is applied to the outer peripheral portion of the sealing member 31, to cover portions of the sealing member 31 bonded to the sealing member 30 and the base body 10a, as shown in FIG. 12. Thereafter the sealant 16 is cured by heating, similarly to the first embodiment. The remaining steps of the manufacturing process are similar to those of the manufacturing process for the semiconductor laser apparatus 100 according to the first embodiment.

In the third modification of the first embodiment, as hereinabove described, the plane area of the sealing member 31 as viewed from the side of the front surface 10e (along arrow A1) is larger than the opening area of the opening 10f, and the sealing member 31 covers the front surface 10e of the base body 10a and an end surface of the sealing member 30 along arrow A1. Thus, the sealing member 31 can reliably seal the opening 10f. The remaining effects of the third modification are similar to those of the first embodiment.

### Second Embodiment

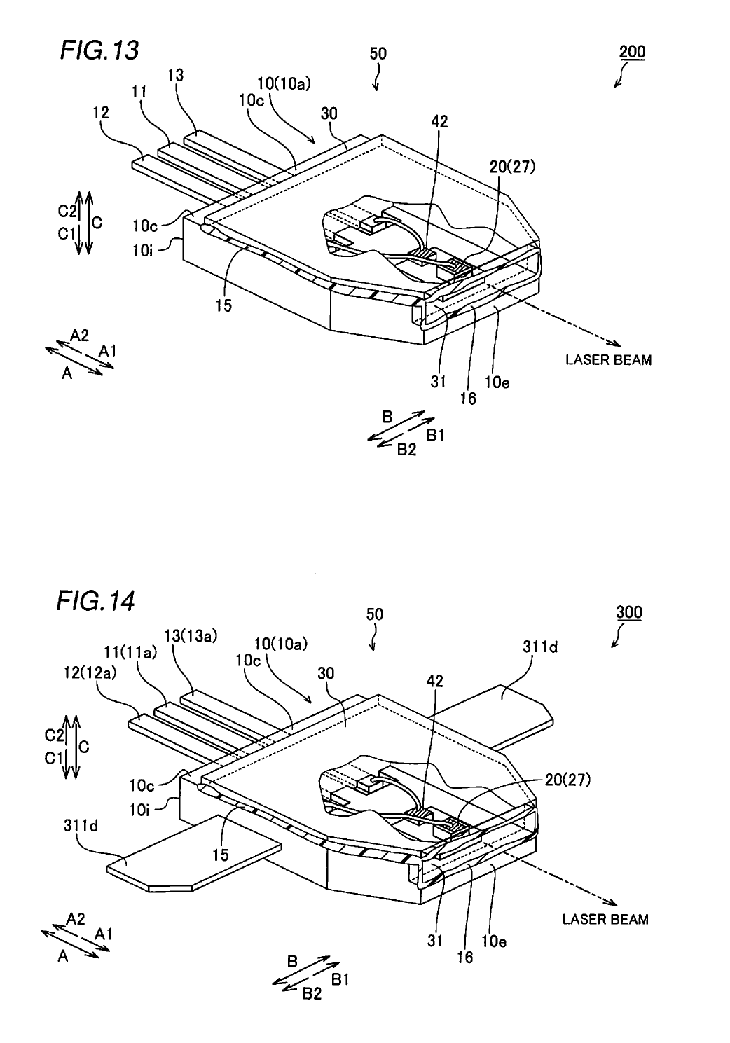

A semiconductor laser apparatus 200 according to a second embodiment of the present invention is now described. The semiconductor laser apparatus 200 is provided with no heat radiation portions 11d (see FIG. 2) passing through a base body 10a from side surfaces along arrow B1 (along arrow B2) to be exposed outward, as shown in FIG. 13. The remaining structure of the semiconductor laser apparatus 200 according to the second embodiment is similar to that of the semiconductor laser apparatus 100 according to the first embodiment, and portions identical to those of the first embodiment are shown by the same reference numerals in FIG. 13.

In a manufacturing process for the semiconductor laser apparatus 200, the heat radiation portions 11d in the first embodiment are not formed, but lead frames are so patterned as to directly couple front end regions 11a with each other by coupling portions 103 when a lead frame similar to that shown in FIG. 6 is prepared. The remaining steps of the manufacturing process are similar to those of the manufacturing process for the semiconductor laser apparatus 100 according to the first embodiment.

As hereinabove described, the semiconductor laser apparatus 200 according to the second embodiment is provided with no heat radiation portions 11d exposed outward from a base portion 20, whereby the semiconductor laser apparatus 200 can be more miniaturized. The remaining effects of the second embodiment are similar to those of the first embodiment.

### Third Embodiment

A semiconductor laser apparatus 300 according to a third embodiment of the present invention is now described. In the semiconductor laser apparatus 300, heat radiation portions 311d having a width (in a direction A) smaller than that of the heat radiation portions 11d in the first embodiment are provided on a rear region of a base body 10a, as shown in FIG. 14. Therefore, no heat radiation portions are arranged on a tapered front portion (along arrow A1) of the semiconductor laser apparatus 300. The remaining structure of the semiconductor laser apparatus 300 is similar to that of the semiconductor laser apparatus 100 according to the first embodiment, and portions identical to those of the first embodiment are shown by the same reference numerals in FIG. 14.

In a manufacturing process for the semiconductor laser apparatus 300, lead frames are so patterned as to form the heat radiation portions 311d having the smaller width (in the direction A) than the heat radiation portions 11d in the first embodiment when a lead frame similar to that shown in FIG. 6 is prepared. The remaining steps of the manufacturing process are similar to those of the manufacturing process for the semiconductor laser apparatus 100 according to the first embodiment.

In the semiconductor laser apparatus 300 according to the third embodiment, as hereinabove described, no heat radiation portions are arranged on the tapered front portion of the base body 10a, whereby the semiconductor laser apparatus 300 can be more easily built into a housing of an optical pickup or the like through an insertion hole or the like. The remaining effects of the third embodiment are similar to those of the first embodiment.

### Fourth Embodiment

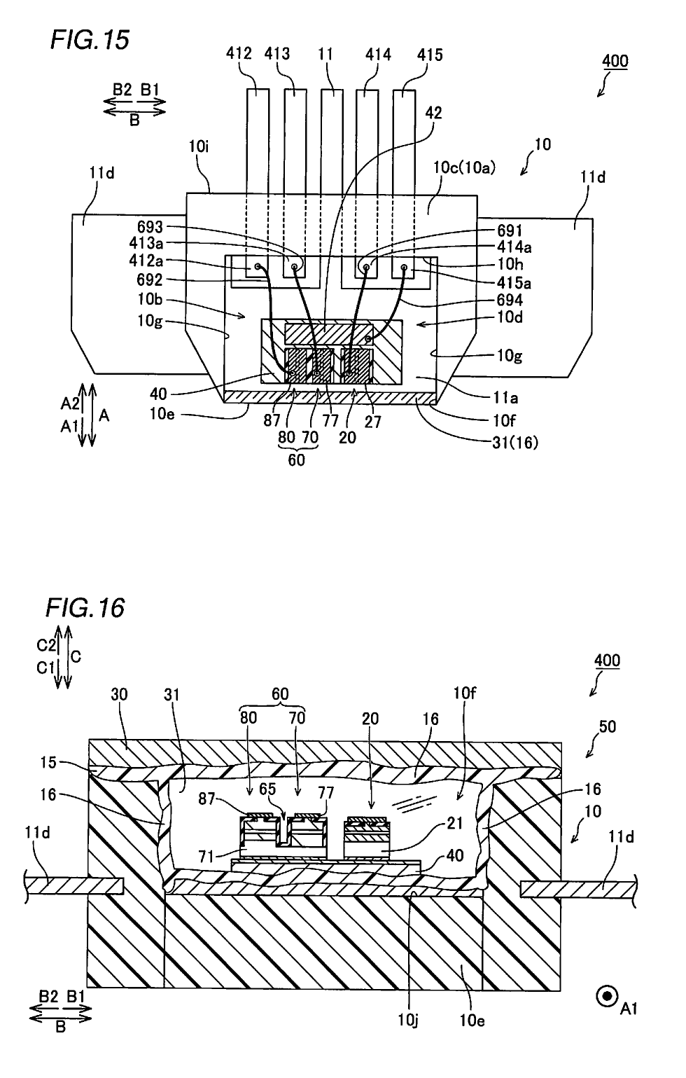

A fourth embodiment of the present invention is now described. In a three-wavelength semiconductor laser apparatus 400 according to the fourth embodiment, a plurality of semiconductor laser chips emitting laser beams of different wavelengths are loaded in a package, as shown in FIG. 15. Referring to FIG. 15, portions identical to those of the first embodiment are shown by the same reference numerals.

In the three-wavelength semiconductor laser apparatus 400 according to the fourth embodiment of the present invention, a two-wavelength semiconductor laser chip 60 monolithically provided with a red semiconductor laser element 70 having a lasing wavelength of about 650 nm and an infrared semiconductor laser element 80 having a lasing wavelength of about 780 nm is bonded onto a submount 40, adjacently to a blue-violet semiconductor laser chip 20. The two-wavelength semiconductor laser chip 60 has a structure obtained by forming the red semiconductor laser element 70 and the infrared semiconductor laser element 80 on the surface of a common n-type GaAs substrate 71 through a recess portion 65. The three-wavelength semiconductor laser apparatus 400 is an example of the “semiconductor laser apparatus” in the present invention. The two-wavelength semiconductor laser chip 60, the red semiconductor laser element 70 and the infrared semiconductor laser element 80 are examples of the “semiconductor laser chip” in the present invention respectively.

As shown in FIG. 15, a base portion 10 is provided with lead frames 11, 412, 413, 414 and 415 made of metal. The lead frames 11 and 412 to 415 are arranged to pass through a base body 10a from the front side (along arrow A1) to the rear side (along arrow A2) in a state insulated from each other. The lead frames 412 to 415 are arranged on the outer sides (along arrows B2 and B1) of the lead frame 11 in a direction B respectively.

Rear end portions of the lead frames 11 and 412 to 415 extending rearward (along arrow A2) are exposed from a rear surface 10i (along arrow A2) of the base body 10a respectively. Front end regions 11a and 412a to 415a of the lead frames 11 and 412 to 415 extending frontward (along arrow A1) are exposed from an inner wall portion 10h respectively, and are arranged on a bottom surface 10j of a recess portion 10b together.

The blue-violet semiconductor laser chip 20 and the two-wavelength semiconductor laser chip 60 are fixed to a substantially central portion of the front end region 11a through the submount 40, to be aligned with each other in a direction B. The blue-violet semiconductor laser chip 20 and the two-wavelength semiconductor laser chip 60 are mounted in a junction-up system, while directing light-emitting surfaces thereof toward a sealing member 31 respectively.

As shown in FIG. 15, an end of a metal wire 491 is bonded to a p-side electrode 27, and another end of the metal wire 491 is connected to the front end region 414a of the lead frame 414. An end of another metal wire 492 is bonded to another p-side electrode 77 formed on the upper surface of the red semiconductor laser element 70, and another end of the metal wire 492 is connected to the front end region 413a of the lead frame 413. An end of still another metal wire 493 is bonded to still another p-side electrode 87 formed on the upper surface of the infrared semiconductor laser element 80, and another end of the metal wire 493 is connected to the front end region 412a of the lead frame 412. An end of a further metal wire 494 is bonded to the upper surface of a PD 42, and another end of the metal wire 494 is connected to the front end region 415a of the lead frame 415.

The base portion 10 and the recess portion 10b are stretched out in the width direction (direction B) as compared with those of the semiconductor laser apparatus 100 according to the first embodiment, and the sealing members 30 and 31 are also stretched out in the width direction. The remaining structure of the three-wavelength semiconductor laser apparatus 400 is similar to that of the semiconductor laser apparatus 100 according to the first embodiment.

In a manufacturing process for the three-wavelength semiconductor laser apparatus 400, the blue-violet semiconductor laser chip 20 and the two-wavelength semiconductor laser chip 60 are arranged in the transverse direction (direction B in FIG. 16) and bonded through the submount 40. Thereafter the p-side electrodes 27, 77 and 87 of the laser chips 20 and 60 and the upper surface of the PD 42 and the front end regions 412a, 413a, 414a and 415a of the lead frames 412, 413, 414 and 415 are wire-bonded to each other respectively. The remaining steps of the manufacturing process are similar to those of the manufacturing process for the semiconductor laser apparatus 100 according to the first embodiment. Effects of the three-wavelength semiconductor laser apparatus 400 are similar to those of the semiconductor laser apparatus 100 according to the first embodiment.

### Fifth Embodiment

An optical pickup 500 according to a fifth embodiment of the present invention is now described. The optical pickup 500 is an example of the “optical apparatus” in the present invention.

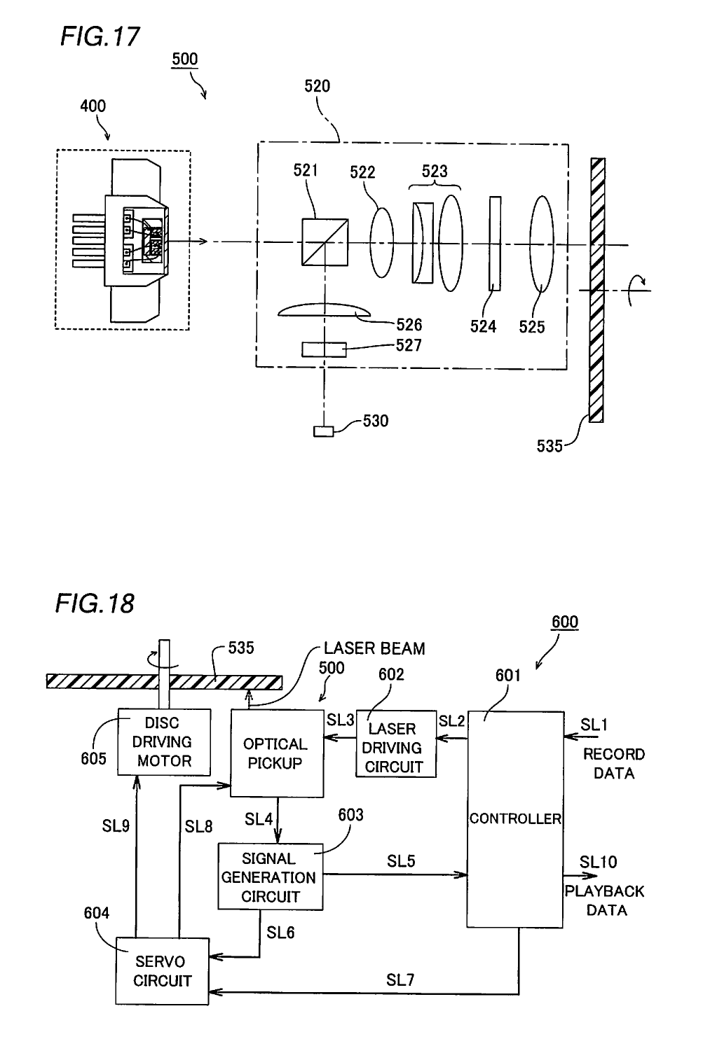

The optical pickup 500 according to the fifth embodiment of the present invention includes a three-wavelength semiconductor laser apparatus 400 (see FIG. 15), an optical system 520 adjusting laser beams emitted from the three-wavelength semiconductor laser apparatus 400 and a light detection portion 530 receiving the laser beams, as shown in FIG. 17.

The optical system 520 has a polarizing beam splitter

(PBS) 521, a collimator lens 522, a beam expander 523, a λ/4 plate 524, an objective lens 525, a cylindrical lens 526 and an optical axis correction device 527.

The PBS 521 totally transmits the laser beams emitted from the three-wavelength semiconductor laser apparatus 400, and totally reflects the laser beams fed back from an optical disc 535. The collimator lens 522 converts the laser beams emitted from the three-wavelength semiconductor laser apparatus 400 and transmitted through the PBS 521 to parallel beams. The beam expander 523 is constituted of a concave lens, a convex lens and an actuator (not shown). The actuator has a function of correcting wave surface states of the laser beams emitted from the three-wavelength semiconductor laser apparatus 400 by varying the distance between the concave lens and the convex lens in response to a servo signal from a servo circuit described later.

The λ/4 plate 524 converts the laser beams, converted to substantially parallel beams by the collimator lens 522, of linear polarization to beams of circular polarization. Further, the λ/4 plate 524 converts the laser beams of circular polarization fed back from the optical disc 535 to beams of linear polarization. The direction of linear polarization in this case is orthogonal to the direction of linear polarization of the laser beams emitted from the three-wavelength semiconductor laser apparatus 400. Thus, the PBS 521 substantially totally reflects the laser beams fed back from the optical disc 535. The objective lens 525 converges the laser beams transmitted through the λ/4 plate 524 on the surface (recording layer) of the optical disc 535. An objective lens actuator (not shown) renders the objective lens 525 movable in a focusing direction, a tracking direction and a tilting direction in response to servo signals (a tracking servo signal, a focusing servo signal and a tilting servo signal) from the servo circuit described later.

The cylindrical lens 526, the optical axis correction device 527 and the light detection portion 530 are arranged along the optical axes of the laser beams totally reflected by the PBS 521. The cylindrical lens 526 provides astigmatic action to the laser beams incident upon the same. The optical axis correction device 527 is constituted of a diffraction grating, and so arranged that spots of zero-order diffracted beams of blue-violet, red and infrared laser beams transmitted through the cylindrical lens 526 coincide with each other on a detection region of the light detection portion 530 described later.

The light detection portion 530 outputs a playback signal on the basis of intensity distribution of the received laser beams. The light detection portion 530 has the detection region of a prescribed pattern, to obtain a focusing error signal, a tracking error signal and a tilting error signal along with the playback signal. The optical pickup 500 including the three-wavelength semiconductor laser apparatus 400 is formed in the aforementioned manner. The three-wavelength semiconductor laser apparatus 400 is inserted into an insertion hole provided in a housing having the optical system 520 built thereinto from the side of a front surface 10c of a base body 10a.

In the optical pickup 500, the three-wavelength semiconductor laser apparatus 400 is so formed that a blue-violet semiconductor laser chip 20, a red semiconductor laser element 70 and an infrared semiconductor laser element 80 can independently emit the blue-violet, red and infrared laser beams when voltages are independently applied between a lead frame 11 and lead frames 412 to 414 respectively. The laser beams emitted from the three-wavelength semiconductor laser apparatus 400 are adjusted by the PBS 521, the collimator lens 522, the beam expander 523, the λ/4 plate 524, the objective lens 525, the cylindrical lens 526 and the optical axis correction device 527 as described above, and thereafter applied onto the detection region of the light detection portion 530.

In a case of playing back information recorded in the optical disc 535, the laser beams emitted from the blue-violet semiconductor laser chip 20, the red semiconductor laser element 70 and the infrared semiconductor laser element 80 respectively are controlled to have constant power and applied to the recording layer of the optical disc 535, so that the playback signal can be obtained from the light detection portion 530. Further, the actuator of the beam expander 523 and the objective lens actuator driving the objective lens 525 can be feedback-controlled respectively by the focusing error signal, the tracking error signal and the tilting error signal output at the same time.

In a case of recording information in the optical disc 535, on the other hand, the laser beams emitted from the blue-violet semiconductor laser chip 20, the red semiconductor laser element 70 and the infrared semiconductor laser element 80 respectively are controlled in power and applied to the optical disc 535, on the basis of the information to be recorded. Thus, the information can be recorded in the recording layer of the optical disc 535. Further, the actuator of the beam expander 523 and the objective lens actuator driving the objective lens 525 can be feedback-controlled respectively by the focusing error signal, the tracking error signal and the tilting error signal output from the light detection portion 530, similarly to the above.

Thus, the information can be recorded in or played back from the optical disc 535 with the optical pickup 500 including the three-wavelength semiconductor laser apparatus 400.

The optical pickup 500 according to the fifth embodiment includes the three-wavelength semiconductor laser apparatus 400. In other words, the blue-violet semiconductor laser chip 20 and a two-wavelength semiconductor laser chip 60 are reliably sealed in a package 50. Thus, the semiconductor laser chips are hard to deteriorate, and the optical pickup 500 highly reliable and capable of withstanding long-term use can be obtained.

### Sixth Embodiment

An optical disc apparatus 600 according to a sixth embodiment of the present invention is now described. The optical disc apparatus 600 is an example of the “optical apparatus” in the present invention.

The optical disc apparatus 600 according to the sixth embodiment of the present invention includes an optical pickup 500, a controller 601, a laser driving circuit 602, a signal generation circuit 603, a servo circuit 604 and a disc driving motor 605, as shown in FIG. 18.

The controller 601 receives record data SL1 generated on the basis of information to be recorded in an optical disc 535. The controller 601 is formed to output signals SL2 and SL7 to the laser driving circuit 602 and the servo circuit 604 respectively in response to the record data SL1 and a first output signal SL5 from the signal generation circuit 603 described later. Further, the controller 601 outputs playback data SL10 on the basis of the first output signal SL5, as described later. The laser driving circuit 602 outputs a signal SL3 for controlling the power of laser beams emitted from a three-wavelength semiconductor laser apparatus 400 in the optical pickup 500 in response to the aforementioned signal SL2. In other words, the three-wavelength semiconductor laser apparatus 400 is formed to be controlled by the controller 601 and the laser driving circuit 602.

The optical pickup 500 applies the laser beams controlled in response to the aforementioned signal SL3 to the optical disc 535, as shown in FIG. 18. A light detection portion 530 in the optical pickup 500 outputs a signal SL4 to the signal generation circuit 603. An optical system 520 (the actuator of the beam expander 523 and the objective lens actuator driving the objective lens 525 shown in FIG. 17) in the optical pickup 500 is controlled by a servo signal SL8 from the servo circuit 604 described later. The signal generation circuit 603 amplifies and operates the signal SL4 output from the optical pickup 500, to output the first output signal SL5 including the playback signal to the controller 601 and to output a second output signal SL6 feedback-controlling the optical pickup 500 and controlling rotation of the optical disc 535 described later to the servo circuit 604.

The servo circuit 604 outputs the servo signal SL8 controlling the optical system 520 in the optical pickup 500 and a motor servo signal SL9 controlling the disc driving motor 605 in response to the second output signal SL6 and the signal SL7 from the signal generation circuit 603 and the controller 601, as shown in FIG. 18. The disc driving motor 605 controls the rotational speed of the optical disc 535 in response to the motor servo signal SL9.

In order to play back information recorded in the optical disc 535, a means identifying the type (a CD, a DVD, a BD or the like), description of which is omitted, of the optical disc 535 selects laser beams of wavelengths to be applied. Then, the controller 601 outputs the signal SL2 to the laser driving circuit 602, so that the laser beams of the wavelengths to be emitted from the three-wavelength semiconductor laser apparatus 400 in the optical pickup 500 are constant in intensity. Further, the three-wavelength semiconductor laser apparatus 400, the optical system 520 and the light detection portion 530 of the optical pickup 500 described above so function that the light detection portion 530 outputs the signal SL4 including the playback signal to the signal generation circuit 603, which in turn outputs the signal SL5 including the playback signal to the controller 601. The controller 601 extracts the playback signal having been recorded in the optical disc 535 by processing the signal SL5, and outputs the playback signal as the playback data SL10. Information such as images and sounds recorded in the optical disc 535 can be output to a monitor, a speaker and the like, for example, with the playback data SL10. The controller 601 also feedback-controls the respective portions on the basis of the signal SL4 from the light detection portion 530.

In order to record information in the optical disc 535, on the other hand, another means, similar to the above, identifying the type of the optical disc 535 selects laser beams of wavelengths to be applied. Then, the controller 601 outputs the signal SL2 to the laser driving circuit 602 in response to the record data SL1 responsive to the information to he recorded. Further, the three-wavelength semiconductor laser apparatus 400, the optical system 520 and the light detection portion 530 of the optical pickup 500 described above so function as to record the information in the optical disc 535, while the controller 601 feedback-controls the respective portions on the basis of the signal SL4 from the light detection portion 530.

Thus, information can be recorded in and played back from the optical disc 535 with the optical disc apparatus 600.

The three-wavelength semiconductor laser apparatus 400 (see FIG. 17) is packaged in the optical pickup 500 in the optical disc apparatus 600 according to the sixth embodiment. In other words, a blue-violet semiconductor laser chip 20 and a two-wavelength semiconductor laser chip 60 are reliably sealed in a package 50. Thus, the semiconductor laser chips 20 and 60 are hard to deteriorate, and the optical disc apparatus 600 highly reliable and capable of withstanding long-term use can be easily obtained.

### Seventh Embodiment

The structure of a projector 700 according to a seventh embodiment of the present invention is now described. In the projector 700, individual semiconductor laser chip and elements constituting an RGB three-wavelength semiconductor laser apparatus 405 are substantially simultaneously turned on. The RGB three-wavelength semiconductor laser apparatus 405 is an example of the “semiconductor laser apparatus” in the present invention, and the projector 700 is an example of the “optical apparatus” in the present invention.

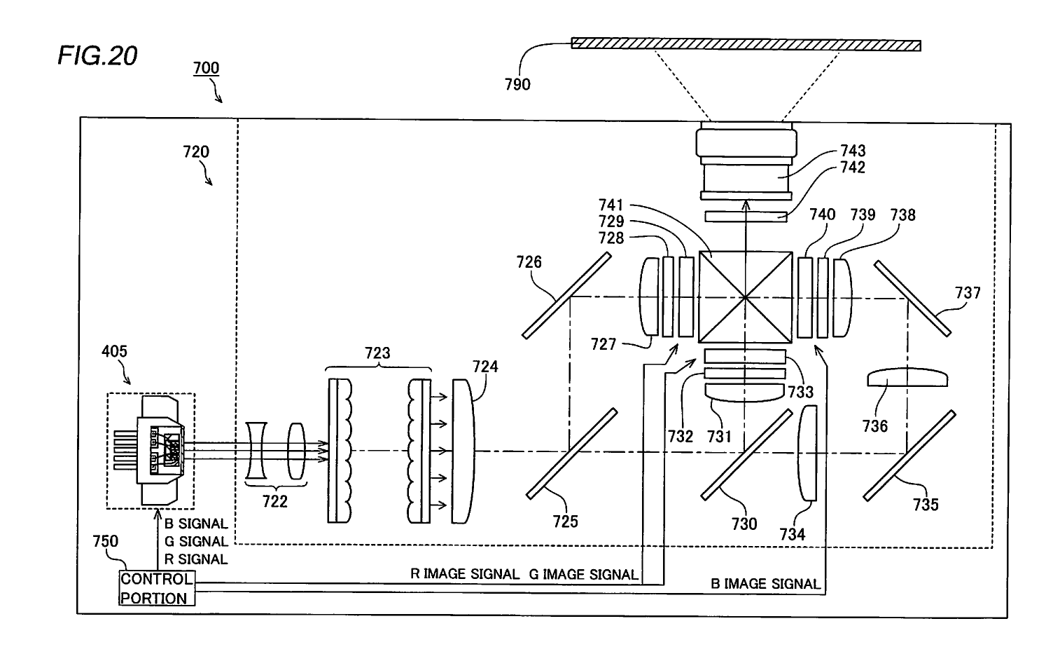

The projector 700 according to the seventh embodiment of the present invention includes the RGB three-wavelength semiconductor laser apparatus 405, an optical system 720 formed by a plurality of optical components and a control portion 750 controlling the RGB three-wavelength semiconductor laser apparatus 405 and the optical system 720, as shown in FIG. 20. Thus, the projector 700 is formed to modulate laser beams emitted from the RGB three-wavelength semiconductor laser apparatus 405 with the optical system 720 and to thereafter project the same on an external screen 790 or the like.

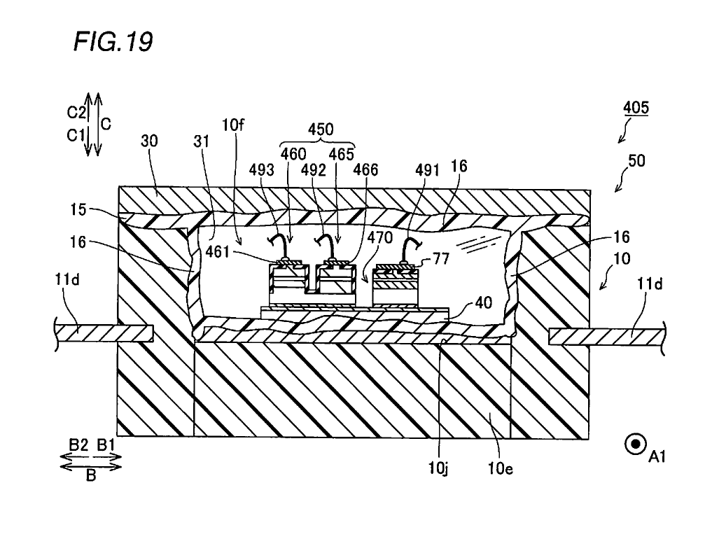

In the RGB three-wavelength semiconductor laser apparatus 405, a two-wavelength semiconductor laser chip 450 monolithically provided with a green semiconductor laser element 460 having a lasing wavelength of about 530 nm for a green (G) beam and a blue semiconductor laser element 465 having a lasing wavelength of about 480 nm for a blue (B) beam and a red semiconductor laser chip 470 having a lasing wavelength of about 655 nm for a red (R) beam are bonded onto a submount 40, as shown in FIG. 19. The two-wavelength semiconductor laser chip 450 has a structure obtained by forming the green semiconductor laser element 460 and the blue semiconductor laser element 465 on the surface of a common n-type GaN substrate 21 through a recess portion 65. The two-wavelength semiconductor laser chip 450 and the red semiconductor laser chip 470 are mounted in a junction-up system while directing light-emitting surfaces toward a sealing member 31 respectively. The two-wavelength semiconductor laser chip 450, the green semiconductor laser element 460, the blue semiconductor laser element 465 and the red semiconductor laser chip 470 are examples of the “semiconductor laser chip” in the present invention.

As shown in FIG. 19, a p-side electrode 77 of the red semiconductor laser chip 470 is connected to a front end region 414a (see FIG. 15) of a lead frame 414 through a metal wire 491. A p-side pad electrode 466 of the blue semiconductor laser element 465 is connected to a front end region 413a (see FIG. 15) of another lead frame 413 through a metal wire 492. A p-side pad electrode 461 of the green semiconductor laser element 460 is connected to a front end region 412a (see FIG. 15) of still another lead frame 412 through a metal wire 493.

The remaining structure of and a manufacturing process for the RGB three-wavelength semiconductor laser apparatus 405 are similar to those of and for the three-wavelength semiconductor laser apparatus 400.

The RGB three-wavelength semiconductor laser apparatus 405 is inserted into an insertion hole provided in a housing having the optical system 720 (see FIG. 20) built thereinto from the side of a front surface 10c of a base body 10a.

As shown in FIG. 20, laser beams emitted from the RGB three-wavelength semiconductor laser apparatus 405 are converted to parallel beams having a prescribed diameter by a dispersion angle control lens 722 formed by a concave lens and a convex lens, and thereafter introduced into a fly-eye integrator 723 in the optical system 720. The fly-eye integrator 723 is so formed that two fly-eye lenses consisting of fly-eye lens groups face each other. Thus, the fly-eye integrator 723 provides lens action to the beams received from the dispersion angle control lens 722 so that the beams are incident upon liquid crystal panels 729, 733 and 740 in uniform quantity distribution. In other words, the beams transmitted through the fly-eye integrator 723 are adjusted to be incident upon the liquid crystal panels 729, 733 and 740 with spreading at an aspect ratio (16:9, for example) corresponding to the sizes of the liquid crystal panels 729, 733 and 740.

A condenser lens 724 condenses the beams transmitted through the fly-eye integrator 723. A dichroic mirror 725 reflects only the red laser beam among the beams transmitted through the condenser lens 724, while transmitting the green and blue laser beams.

The red laser beam is parallelized by a lens 727 through a mirror 726, and thereafter introduced into the liquid crystal panel 729 through an incidence-side polarizing plate 728. The liquid crystal panel 729 is driven in response to a red image signal (R image signal), thereby modulating the red laser beam.

Another dichroic mirror 730 reflects only the green laser beam in the beams transmitted through the dichroic mirror 725, while transmitting the blue laser beam.

The green laser beam is parallelized by another lens 731 and thereafter introduced into the liquid crystal panel 733 through another incidence-side polarizing plate 732. The liquid crystal panel 733 is driven in response to a green image signal (G image signal), thereby modulating the green laser beam.

The blue laser beam transmitted through the dichroic mirror 730 passes through a lens 734, a mirror 735, a lens 736 and a mirror 73, is parallelized through a lens 738, and thereafter introduced into the liquid crystal panel 740 through still another incidence-side polarizing plate 739. The liquid crystal panel 740 is driven in response to a blue image signal (B image signal), thereby modulating the blue laser beam.

Thereafter the red, green and blue laser beams modulated by the liquid crystal panels 729, 733 and 740 are synthesized by a dichroic prism 741, and thereafter introduced into a projection lens 743 through an emitting-side polarizing plate 724. The projection lens 743 stores a lens group for imaging projected beams on a projection surface (screen 795) and an actuator for controlling zooming and focusing of the projected image by partially displacing the lens group in the optical axis direction.

In the projector 700, the control portion 750 supplies stationary voltages as an R signal related to driving of the red semiconductor laser chip 470, a G signal related to driving of the green semiconductor laser element 460 and a B signal related to driving of the blue semiconductor laser element 465 to the laser chip and elements of the RGB three-wavelength semiconductor laser apparatus 405. Thus, the projector 700 is so formed that the red semiconductor laser chip 470, the green semiconductor laser element 460 and the blue semiconductor laser element 465 of the RGB three-wavelength semiconductor laser apparatus 405 lase substantially at the same time. Further, the projector 700 is so formed that the control portion 750 controls the beams emitted from the red semiconductor laser chip 470, the green semiconductor laser element 460 and the blue semiconductor laser element 465 of the RGB three-wavelength semiconductor laser apparatus 405 in intensity thereby controlling the hue, brightness etc. of pixels projected on the screen 790. Thus, the control portion 750 projects a desired image on the screen 790.

The projector 700 loaded with the RGB three-wavelength semiconductor laser apparatus 405 is formed in the aforementioned manner.

### Eighth Embodiment

The structure of a projector 705 according to an eighth embodiment of the present invention is now described. In the projector 705, individual semiconductor laser chip and elements constituting an RGB three-wavelength semiconductor laser apparatus 405 are turned on in a time-series manner.

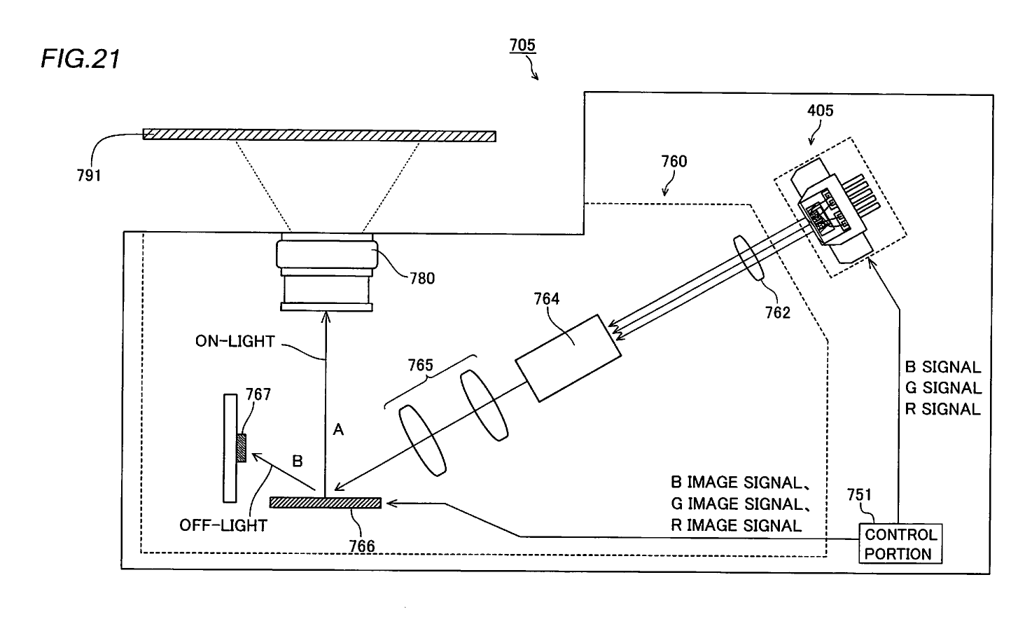

The projector 705 according to the eighth embodiment of the present invention includes the RGB three-wavelength semiconductor laser apparatus 405, an optical system 760 and a control portion 751 controlling the RGB three-wavelength semiconductor laser apparatus 405 and the optical system 760, as shown in FIG. 21. Thus, the projector 705 is so formed that the optical system 760 modulates laser beams emitted from the RGB three-wavelength semiconductor laser apparatus 405 and thereafter projects the same on a screen 791 or the like.

The RGB three-wavelength semiconductor laser apparatus 405 is inserted into an insertion hole provided in a housing having the optical system 760 built thereinto from the side of a front surface 10c of a base body 10a.

In the projector 705, a lens 762 converts the laser beams emitted from the RGB three-wavelength semiconductor laser apparatus 405 into parallel beams respectively and introduces the same to a light pipe 764.

The inner surface of the light pipe 764 is formed by a mirror surface, and the laser beams advance in the light pipe 764 while the same are repetitively reflected on the inner surface thereof. At this time, the laser beams advancing the light pipe 764 are uniformized in intensity distribution due to multiple reflection therein. Then, the laser beams outgoing from the light pipe 764 are introduced into a digital micro-mirror device (DMD) 766 through a relay optical system 765.

The DMD 766 is formed by a group of small mirrors arranged in the form of a matrix. The DMD 766 has a function of expressing (modulating) the gradation of each pixel by switching a light reflection direction on each pixel position between a first direction A toward a projection lens 780 and a second direction B turning away from the projection lens 780. Among the laser beams incident upon each pixel position, a beam (ON-light) reflected in the first direction A is introduced into the projection lens 780 and projected on a projection surface (screen 791). On the other hand, a beam (OFF-light) reflected by the DMD 766 in the second direction B is not introduced into the projection lens 780, but absorbed by a beam absorber 767.

The projector 705 is so formed that the control portion 751 supplies pulsed power to the RGB three-wavelength semiconductor laser apparatus 405, thereby dividedly periodically driving a red semiconductor laser chip 470, a green semiconductor laser element 460 and a blue semiconductor laser element 465 of the RGB three-wavelength semiconductor laser apparatus 405 one by one in a time-series manner. The control portion 751 controls the DMD 766 of the optical system 760 to modulate the laser beams in association with the gradations of respective pixels (R, G and B) in synchronization with the driven states of the red semiconductor laser chip 470, the green semiconductor laser element 460 and the blue semiconductor laser element 465 respectively.

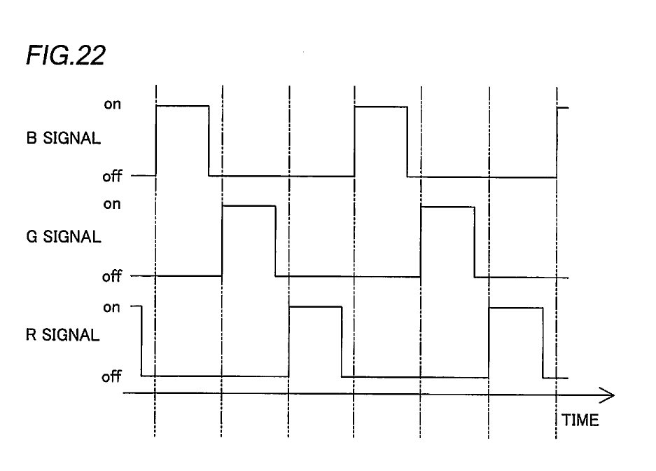

More specifically, the control portion 751 (see FIG. 21) supplies an R signal related to the driving of the red semiconductor laser chip 470 (see FIG. 21), a G signal related to the driving of the green semiconductor laser element 460 (see FIG. 21) and a B signal related to the driving of the blue semiconductor laser element 465 (see FIG. 21) to the semiconductor laser chip and elements of the RGB three-wavelength semiconductor laser apparatus 405 in a state divided in a time-series manner not to overlap each other, as shown in FIG. 22. The control portion 751 further outputs a B image signal, a G image signal and an R image signal to the DMD 766 in synchronization with the B signal, the G signal and the R signal respectively.

Thus, the blue semiconductor laser element 465 emits a blue laser beam on the basis of the B signal in the timing chart shown in FIG. 22, and the DMD 766 modulates the blue laser beam on the basis of the B image signal at this timing. Then, the green semiconductor laser element 460 emits a green laser beam on the basis of the G signal output subsequently to the B signal, and the DMD 766 modulates the green laser beam on the basis of the G image signal at this timing. Then, the red semiconductor laser chip 470 emits a red laser beam on the basis of the R signal output subsequently to the G signal, and the DMD 766 modulates the red laser beam on the basis of the R image signal at this timing. Thereafter the blue semiconductor laser element 465 emits a blue laser beam on the basis of the B signal output subsequently to the R signal, and the DMD 766 modulates the blue laser beam again on the basis of the B image signal at this timing. These operations are so repeated that images formed by application of the laser beams based on the B image signal, the G image signal and the R image signal are projected on the projection surface (screen 791).

The projector 705 loaded with the RGB three-wavelength semiconductor laser apparatus 405 is formed in the aforementioned manner.

In each of the projectors 700 and 705 according to the seventh and eighth embodiments, the RGB three-wavelength semiconductor laser apparatus 405 (see FIG. 19) is packaged in the projector 700 or 705. In other words, the red semiconductor laser chip 470, the green semiconductor laser element 460 and the blue semiconductor laser element 465 are reliably sealed in a package 50. Thus, the semiconductor laser chip and elements are hard to deteriorate, and the projector 700 or 705 highly reliable and capable of withstanding long-term use can be easily obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the sealant 15 made of epoxy resin containing bisphenol A and bisphenol F without containing halogen or EVOH resin is employed as the “sealant” in the present invention in each of the first to eighth embodiments, the present invention is not restricted to this. According to the present invention, the sealant may alternatively be made of epoxy resin containing a curing agent prepared from cyclic fatty acid, for example. Further alternatively, the sealant may be made of fluorine-based organic matter such as fluorine-based grease prepared from fluororesin, a polymer prepared from perfluoropolyether and tetrafluoroethylene, a polymer prepared from hexafluoropropylene or a polymer prepared from vinylidene fluoride, polyvinyl alcohol, ethylene or a one-part epoxy-based adhesive. Further alternatively, the sealant may be made of a silicone rubber-based tackifier. When the sealant is made of a one-part epoxy-based adhesive or the like, volatile components are preferably sufficiently removed previously by heating.

While the sealing member 31 made of translucent silicon resin is employed as the “second sealing member” in the present invention in each of the first to eighth embodiments, the present invention is not restricted to this. According to the present invention, the sealing member may alternatively be formed by a member of thermosetting fluororesin or borosilicate glass provided with a gas barrier layer on the surface thereof or a hard and translucent member made of quartz or acrylic resin (transparent acrylic resin). The aforementioned gas barrier layer may be formed by a dielectric film of Al₂O₃, SiO₂ or ZrO₂, or a resin film of an ethylene-polyvinyl alcohol copolymer or polyvinyl alcohol having low gas permeability. When the gas barrier layer is constituted of a multilayer metal oxide film made of Al₂O₃ or ZrO₂, the metal oxide film can also serve as a reflection preventing layer.

While the entirely translucent sealing member 31 is employed as the “second sealing member” in the present invention in each of the first to eighth embodiments, the present invention is not restricted to this. According to the present invention, the “second sealing member” in the present invention may alternatively be prepared by providing a “window portion” made of the aforementioned translucent material only on a portion transmitting the laser beams while forming the remaining portion by a non-translucent material such as a metal plate. In this case, the second sealing member can be formed by an aluminum plate, a Cu plate, a Cu alloy plate of nickel silver or the like, an alloy plate of Sn, Ni or Mg, a stainless plate or a ceramic plate.

While the sealing member 30 formed by the aluminum plate is employed as the “first sealing member” in the present invention in each of the first and third to eighth embodiments, the present invention is not restricted to this. According to the present invention, the “first sealing member” may alternatively be formed by a Cu plate, a Cu alloy plate of nickel silver or the like, an alloy plate of Sn, Ni or Mg, a stainless plate or a ceramic plate. The first and second sealing members are preferably formed by metal plates having high heat radiation properties, so that the heat generated by the semiconductor laser chip(s) can be easily radiated outward.

While the base body 10a (opening 10d) is sealed in the state forming the sealant 15 made of EVOH resin on the rear surface of the sealing member 30 formed by the aluminum plate in the second modification of the first embodiment, the present invention is not restricted to this. According to the present invention, the sealing member 30 may alternatively be made of polyamide resin or epoxy resin, for example, other than the metal (aluminum), and may be mounted on the base body 10a through the sealant 15 arranged on the rear surface thereof. When the sealing member 30 is made of the aforementioned resin material, low molecular siloxane or volatile organic gas can be more effectively inhibited from infiltrating into the package 50 due to the EVOH resin (sealant 15) rich in gas barrier properties.

While the base body 10a is made of polyamide resin (PA) in each of the first to eighth embodiments, the present invention is not restricted to this. According to the present invention, the base body may alternatively be made of epoxy resin, polyphenylene sulfide resin (PPS) or a liquid crystal polymer (LCP). However, the polyamide resin is suitable as a resin material for molding the base body, in a point that the same generates volatile gas in a smaller quantity than other resin materials described above. In the case of sealing the base body with the “first sealing member” and the “second sealing member” in the present invention, an adsorbent such as synthetic zeolite or silica gel is preferably set in the package in a state worked into a size of at least about 0.5 mm and not more than about 1.0 mm, along with the semiconductor laser chip(s). Thus, the absorbent can absorb volatile gas components generated from the base body, whereby the laser chip(s) can be further improved in reliability. In a case of using the aforementioned PPS or LCP, heat treatment is preferably performed after formation of the base body. Thus, moisture, a solvent etc. contained in the resin can be previously evaporated.

When prepared from polyamide resin or the aforementioned epoxy resin, polyphenylene sulfide resin or a liquid crystal polymer, the base body 10a may be molded in the state of a mixture obtained by introducing a gas absorbent into the resin material at a prescribed ratio. The gas absorbent is preferably prepared from silica gel or heat-treated synthetic zeolite. Further, the gas absorbent is preferably prepared from a granular absorbent having a particle diameter of at least several 10 μm and not more than several 100 μm. Thus, the gas absorbent can absorb low molecular siloxane present in the atmosphere or volatile organic gas generated from the base body or the like, to reduce concentration of organic gas etc. in the package 50.

While the depth of the recess portion 10b of the base portion 10 is set to about half the thickness t1 of the base body 10a in each of the first to eighth embodiments, the present invention is not restricted to this. According to the present invention, the depth of the recess portion 10b may alternatively be larger or smaller than half the thickness t1, for example.

While the sealing member 30 preferably has the width W1 in the rear portion (along arrow A2) and the width W1 (W1>W2) in the front portion (along arrow A1) as shown in each of the first to eighth embodiments, the sealing member 30 may simply have a width capable of covering the opening 10d, and the widths W1 and W2 may be equal to each other.

While the base body 10a has the outer shape so tapered that the width (in the direction B) thereof is reduced from the rear portion (along arrow A2) toward the front surface 10e in each of the first to eighth embodiments, the present invention is not restricted to this. According to the present invention, the base body 10a may not be tapered, but may alternatively have the same width from the rear portion (along arrow A2) toward the front surface 10e.

What is claimed is:

1. A semiconductor laser apparatus comprising:
a semiconductor laser chip; and
a package sealing said semiconductor laser chip, wherein
said package includes a base body made of resin, a first sealing member mounted on an upper surface of said base body and a translucent second sealing member mounted on a front surface of said base body,
said base body has an opening passing through said base body from said upper surface to said front surface, and
the side of said opening closer to said upper surface is sealed with said first sealing member, while the side of said opening closer to said front surface is sealed with said second sealing member.

2. The semiconductor laser apparatus according to claim 1, wherein
said first sealing member and said second sealing member are mounted on said base body through sealants made of resin respectively.

3. The semiconductor laser apparatus according to claim 2, wherein
said first sealing member and said second sealing member are bonded to each other through said sealants made of resin, thereby sealing said opening of said base body from said upper surface to said front surface.

4. The semiconductor laser apparatus according to claim 1, wherein
the plane area of said first sealing member as viewed from the side of said upper surface is rendered larger than the opening area of said opening on the side closer to said upper surface, and
the side of said opening closer to said upper surface is covered with said first sealing member.

5. The semiconductor laser apparatus according to claim 4, wherein
said base body is concavely formed with said opening, and
said second sealing member is arranged to seal the side of said opening closer to said front surface, surrounded by the inner side surface on the side closer to said front surface of said base body and the lower surface of said first sealing member sealing the side closer to said upper surface of said base body.

6. The semiconductor laser apparatus according to claim 5, wherein
said second sealing member is fitted into the inner side surface of said opening on the side closer to said front surface.

7. The semiconductor laser apparatus according to claim 5, further comprising a metal plate receiving said semiconductor laser chip thereon on the inner bottom surface of said package, wherein
said second sealing member is arranged to seal an opening region in a state coming into contact with a front end surface of said metal plate closer to said front surface.

8. The semiconductor laser apparatus according to claim 5, wherein
the plane area of said second sealing member as viewed from the side of said front surface is larger than the opening area of said opening on the side closer to said front surface, and
the surface on the side closer to said front surface of said base body and the end surface of said first sealing member on the side closer to said front surface are covered with said second sealing member.

9. The semiconductor laser apparatus according to claim 1, wherein
the side of said opening closer to said front surface is notched from a first end portion to a second end portion of said front surface of said base body along a direction orthogonal to a light-emitting direction of said semiconductor laser chip and the thickness direction of said base body, and
said second sealing member is fitted into the space between said first end portion and said second end portion of said front surface of said base body.

10. The semiconductor laser apparatus according to claim 9, wherein
the widths of said opening along said direction orthogonal to said light-emitting direction of said semiconductor laser chip and the thickness direction of said base body are substantially equal to each other on the side closer to said upper surface and the side closer to said front surface.

11. The semiconductor laser apparatus according to claim 2, wherein
outer edge portions of sealed regions of said opening are filled up with said sealants not to generate holes penetrating from an inside of sealing space to an outside thereof.

12. The semiconductor laser apparatus according to claim 11, wherein
said sealants protrude from said sealed regions of said opening at least into a sealing space of said package.

13. The semiconductor laser apparatus according to claim 2, wherein
said sealants are made of any of fluororesin, epoxy resin, ethylene-vinyl alcohol resin and a silicone rubber-based tackifier.

14. The semiconductor laser apparatus according to claim 1, wherein
said base body has an outer shape tapered toward said front surface as viewed from the side of said upper surface.

15. The semiconductor laser apparatus according to claim 14, wherein
said first sealing member has an outer shape tapered toward the side closer to said front surface as viewed from the side of said upper surface.

16. The semiconductor laser apparatus according to claim 2, wherein
said sealants are provided to extend onto a surface of said first sealing member other than a bonded region bonded to said base body.

17. The semiconductor laser apparatus according to claim 1, further comprising a metal plate receiving said semiconductor laser chip thereon on the inner bottom surface of said package, wherein
said metal plate includes a heat radiation portion extending outward from said base body.

18. The semiconductor laser apparatus according to claim 17, wherein
said base body has an outer shape tapered toward said front surface as viewed from the side of said upper surface, and
said heat radiation portion extends outward from an outer side surface other than a region tapered toward said front surface of said base body.

19. The semiconductor laser apparatus according to claim 1, wherein
said semiconductor laser chip is a nitride-based semiconductor laser chip.

20. An optical apparatus comprising:
a semiconductor laser apparatus including a semiconductor laser chip and a package sealing said semiconductor laser chip; and
an optical system controlling a beam emitted from said semiconductor laser apparatus, wherein
said package includes a base body made of resin, a first sealing member mounted on an upper surface of said base body and a translucent second sealing member mounted on a front surface of said base body,
said base body has an opening passing through said base body from said upper surface to said front surface, and
the side of said opening closer to said upper surface is sealed with said first sealing member, while the side of said opening closer to said front surface is sealed with said second sealing member.
